(19) United States
(12) Patent Application Publication
(10) Pub. No.: US 2020/0232098 A1
(43) Pub. Date: Jul. 23, 2020

(54) PATTERN FORMATION USING CATALYST BLOCKER

(71) Applicant: AVERATEK CORPORATION, Santa Clara, CA (US)

(72) Inventors: Michael Riley VINSON, Sunnyvale, CA (US); Sunity K. SHARMA, Fremont, CA (US); Shinichi IKETANI, Sunnyvale, CA (US); Calvin CHEN, Daly City, CA (US); Shalaka RAHANGDALE, Morrisville, NC (US)

(21) Appl. No.: 16/748,335

(22) Filed: Jan. 21, 2020

Related U.S. Application Data
(60) Provisional application No. 62/795,391, filed on Jan. 22, 2019.

(51) Int. Cl. C23C 18/18; H05K 3/04; H05K 3/02; C23C 18/16

(52) U.S. Cl. CPC C23C 18/1831; H05K 3/04; H05K 2203/107; C23C 18/1605; H05K 2203/072; H05K 3/027

(57) ABSTRACT

Methods of patterning electroless metals on a substrate are presented. The substrate is covered by a blocking reagent. After formation of a catalyst blocking layer on the substrate, portions of the catalyst blocking layer are removed to form a circuit pattern. A catalyst is placed the surfaces of both the catalyst blocking layer and the exposed substrate. The catalyst blocking layer prevents or reduces catalytic activity of the catalyst. Electroless metal plating is performed to plate a metal at the active portions of the catalyst.

This application claims the benefit of U.S. Provisional Patent No. 62/795,391, filed Jan. 22, 2019, which is incorporated by reference in its entirety herein.

### FIELD OF THE INVENTION

The field of the invention relates to methods and systems for patterning metal plating on a substrate. In particular, the present invention relates to methods and systems that utilize a catalyst blocking reagent that deactivates the substrate and removes the blocking reagent in the selective area to make the selective area active for metal plating.

### BACKGROUND

The following description includes information that may be useful in understanding the present invention. It is not an admission that any of the information provided herein is prior art or relevant to the presently claimed invention, or that any publication specifically or implicitly referenced is prior art.

Electroless metal deposition uses a redox reaction to deposit a layer of metals on a substrate without passage of an electric current. In this process, several types of metals can be used as catalysts for deposition of the metals. For example, palladium, platinum, and silver are well known catalysts for initiating electroless metal deposition on substrates. The catalysts can be generated and deposited on a substrate in various forms (e.g., palladium can be deposited as colloidal palladium, ionic palladium, etc.). Thus, the catalysts facilitate subsequent deposition of electroless metals (e.g., copper, tin, etc.) from solutions of metal salts.

U.S. Pat. No. 4,261,800 to Beckengbaugh and U.S. Pat. No. 3,791,340 to Ferrara disclose electroless metal plating after deactivation of a catalyst. In these patents, the catalyst entirely covers the substrate and the catalyst is deactivated according to the negative circuit pattern, and then electroless metal plating is performed.

All publications identified herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

There are at least two disadvantages in this method. First, the surface of the substrate is not flat in view of vertical cross section. Because electroless metal plating is performed on the top of the substrate and the catalyst, the metal portion is extended against the substrate in the view of the vertical section, such that the metal portion can be easily damaged by external force. Second, an expensive catalyst material is wasted because it is used but ultimately deactivated.

U.S. Pat. No. 9,699,914 to Reddy et al. discloses electroless metal plating by use of a blocking reagent. In this patent, the blocking reagent covers the substrate in negative circuitry pattern. This is achieved by use of ink-jet printing, screen-printing, pad printing, and gravure printing. These machines are relatively expensive and take a long time to finish the task.

Thus, there is still a need for improved methods and systems for patterning electroless metal plating on a substrate.

### SUMMARY OF THE INVENTION

The inventive subject matter contemplates systems, methods, and devices for depositing a metal on a substrate. A catalyst blocker is placed on the substrate, and a portion of the catalyst blocker and substrate adjacent to the blocker is removed. A catalyst is placed on a surface of the substrate and on a surface of the catalyst blocker, such that the catalyst on the surface of the substrate is active, and the catalyst on the surface of the catalyst blocker is inactive. The metal (e.g., conductors known in the art) is then deposited, preferably electrolessly, on the active catalyst.

Typically, the step of removing a portion of catalyst blocker precedes the step of placing the catalyst on the surface of the substrate. The catalyst blocker usually includes a blocking agent (e.g., selenium (preferably amorphous selenium), dithiocarbamate, etc.), and a resin (e.g., an epoxy, a polyurethane, a polyester, a silicone, a melamine resin, a polyimide, a cyanate ester, a phenol resin, a bis-maleimide/triazine, a fluorocarbon, a liquid crystal resin, a urea resin, etc.). The resin further includes a solvent (e.g., a carbon disulfide solvent, a solvent for the resin (e.g., solvent for an epoxy, a polyurethane, a polyester, a silicone, a melamine resin, a polyimide, a cyanate ester, a phenol resin, a bis-maleimide/triazine, a fluorocarbon, a liquid crystal resin, a urea resin, etc.), etc.). The substrate is typically at least one of a polyimide, a cloth, a plastic, a metal, or a ceramic.

The catalyst blocker is typically removed by one of laser ablation, milling, or a combination thereof, though additional methods known in the art are contemplated as appropriate. Laser ablation is generally performed via a UV, a CO2, a YAG, or an excimer laser. Milling is typically a numerical control (NC) mill.

In some embodiments, the catalyst is at least one of palladium, platinum, rhodium, iridium, cobalt, nickel, copper, gold, silver, or alloys or combinations thereof. It is contemplated that the catalyst is placed on the substrate or catalyst blocker via a catalyst precursor (e.g., ink precursor followed by thermal reduction, chemical reduction, etc., to deposit active catalyst), though other methods such as physical vapor deposition (PVD), chemical vapor deposition (CVD), or sputtering, etc., can be used as may be appropriate. The metal that is plated is preferably at least one of copper, nickel, cobalt, tin, silver, gold, palladium, platinum, or rhodium, or combinations thereof. The portion of the catalyst blocker, and adjacent substrate, is preferably removed in the shape of a pattern, for example the pattern of conductive material in an electrical circuit.

Methods of creating a pattern for plating a metal to a substrate are further contemplated. A catalyst blocker is placed on the substrate, and a portion of the catalyst blocker and adjacent substrate is removed to form at least a portion of the pattern. A catalyst is placed on a surface of the substrate and on a surface of the catalyst blocker, such that the catalyst on the surface of the substrate is active, and the catalyst on the surface of the catalyst blocker is inactive, thus forming the pattern for plating the metal to the substrate. Preferably, the pattern forms at least part of the conductive material in an electrical circuit. Typically, the pattern of catalyst is then electroless plated with a conductor, though that step is not required for this embodiment.

The inventive subject matter further provides apparatus, systems and methods for patterning of electroless metal using a catalyst blocking reagent. A catalyst blocking reagent is placed all over a substrate to form the substrate with a catalyst blocking layer. In some embodiments, a photo-imageable dielectric material is placed over the catalyst blocking reagent in a negative circuitry pattern, thus allowing complete separation between a negative circuit from an electrically conductive positive circuit. Typically, the dielectric material comprises at least one of the group consisting of titanium oxide, calcium titanate, and strontium titanate. The catalyst blocking layer on the positive circuitry pattern is then ablated. The ablation of the catalyst blocking layer is performed by UV, CO₂, YAG, excimer laser, or and mechanical trimmer (e.g., NC milling).

After ablation of the catalyst blocking layer, a catalyst is placed all over the surface of both the catalyst blocking layer and the adjacent substrate. Since the catalyst blocking layer deactivates, inhibits, or prevents catalytic activity of the catalyst layer that it covers, the catalyst is only active where it is not in contact with the catalyst blocking layer. The catalyst includes at least one of palladium, platinum, gold and silver. Excessive catalyst can optionally be removed from the substrate by rinsing with a rinsing reagent (e.g., deionized water, chemical solution, etc.).

An electroless metal layer is then plated onto the active portions of the catalyst layer. The electroless metal is only plated onto the active catalyst layer (not in contact with catalyst blocking layer), and is not plated to the inactive portion of the catalyst layer (in contact with catalyst blocking layer). The metal is at least one of copper, nickel, tin, silver, gold, palladium, platinum and rhodium. It is noteworthy that the metal is not cross-sectionally extended, but is restricted by the catalyst blocking reagent. This allows complete separation of a negative circuit from an electrical conductible positive circuit.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1 illustrates a flowchart of one embodiment to show a method of patterning of electroless metals

FIG. 2 illustrates a cross-sectional view of steps in depositing electroless metal using catalyst blocking reagent corresponding to FIG. 1.

### DETAILED DESCRIPTION

The present invention relates to methods, systems and devices for creating patterns to plate metals on substrates and otherwise plating metals on substrates. In particular, it relates to methods and systems that utilize a catalyst blocking reagent that deactivates, inhibits, or prevents catalyst activity, thereby restricting plating of a metal to active portions of the catalyst. The principles and operations for such methods and systems, according to the present invention, may be better understood with reference to the accompanying description and drawings.

The present invention includes a method of patterning of electroless metals using electroless plating. Electroless metal plating uses a redox reaction to deposit metal on an object without the passage of an electric current. One of the main advantages of electroless metal plating is that electroless plating allows electroless metal to be deposited evenly along edges, inside of holes, and over irregular shaped objects, which are difficult to plate evenly when electroplating with electric current.

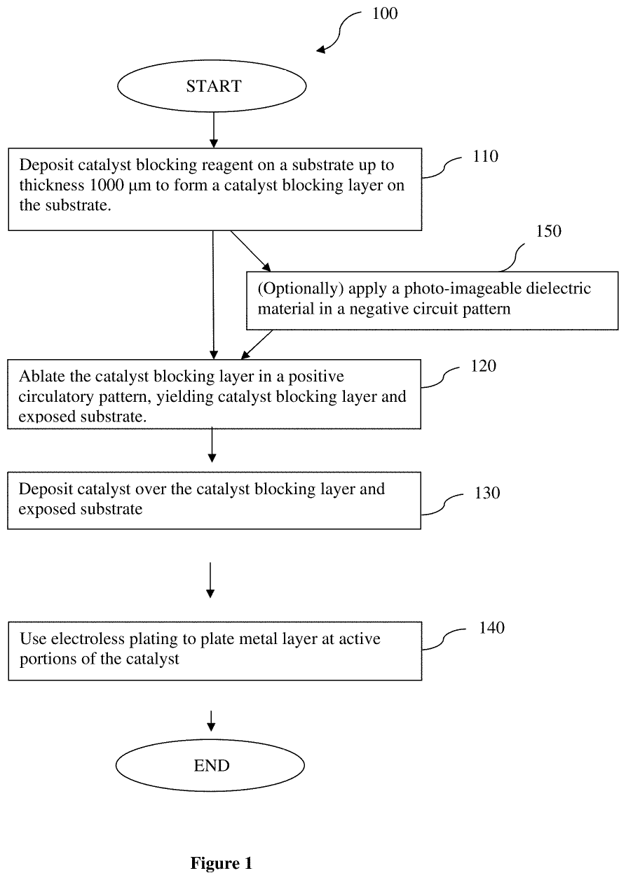

FIG. 1 illustrates a preferred embodiment of method 100 of patterning an electroless metal using catalyst blocking reagent. In this embodiment, the method begins with a step 110 of depositing catalyst blocking reagent on the substrate to form a substrate with a catalyst blocking layer. Any suitable types of material, rigid or flexible, can be used as a substrate. For example, a substrate can comprise a material of polyimide, a cloth, a plastic, a metal, and a ceramic. It is further contemplated that catalyst blocking reagent includes at least one of selenium, dithiocarbamaten, a resin, or a solvent, or combinations thereof.

It is especially preferred that the catalyst blocking layer has an average thickness of less than 50 μm, more preferably less than 10 μm, and most preferably less than 1 μm. In some embodiments, the thickness of the catalyst blocking layer is achieved by modulating the concentration of catalyst blocking agent in the solution, for example decreasing concentration of catalyst blocking agent to decrease thickness of catalyst blocking layer, increasing concentration to increase thickness, etc., or prolonging or shortening the duration of applying the catalyst blocking solution to the target area.

Once the catalyst blocking agent is deposited on the substrate, the method continues with step 120 of ablating the catalyst blocking agent in a negative circuit pattern. Viewed from another perspective, catalyst blocking agent is removed to expose the substrate in the pattern of a conductive circuit, or portions thereof. The ablation can be performed by using UV, CO₂, YAG, excimer laser, mechanical trimmer (NC milling). These methods preferably utilize laser or gas to make an ablation as laser or gas allows to make narrow electric pathways with a consistent width and great accuracy in terms of positioning, such that small and accurate electric circuits can be generated to satisfy the demand for products which are compact with intricate conductive circuitry.

The method continues with step 130 of depositing catalyst on the catalyst blocking layer and the exposed substrate. Where the catalyst is deposited on the catalyst blocking layer, the catalyst is inactive, has reduced activity, or is otherwise blocked from enabling electroless plating. Where the catalyst is deposited directly to the substrate, or is otherwise not in contact with the catalyst blocking agent, the catalyst is active and can be used for electroless metal plating. The catalysts are preferably at least one of palladium, platinum, gold and silver.

The method includes a step 140 of depositing an electroless metal layer at active portions of the catalyst. The plated metals are preferably at least one of copper, nickel, tin, silver, gold, palladium, platinum and rhodium.

In some embodiments, an optional step 150 of applying a photo-imageable dielectric material in a negative circulatory pattern is included prior to step 120 of ablating the catalyst blocking agent. In this way, the negative circulatory pattern should be electrically isolated, being completely separated from electrically conductible circuit.

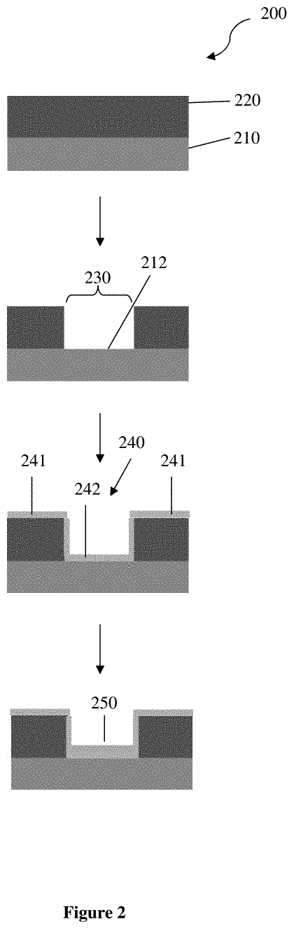

FIG. 2 provides a cross sectional view of electroless metal plating using the method described in the current invention. Substrate 210 is covered by catalyst blocking agent 220. Portions of catalyst blocking agent 220 are ablated or otherwise removed (see recess 230) to expose substrate 210 in the pattern of a conductive circuit (see exposed substrate 212). Once portions of catalyst blocking agent 220 are removed (see recess 230), catalyst 240 is placed over surfaces of both the catalyst blocking layer 220 and exposed portions of substrate 210 (see 212). Catalyst 240 is inactive where it contacts catalyst blocking reagent 220 (see e.g. portions 241), but is active where it contacts exposed substrate 212 (see portion 242). Metal layer 250 is then electroless plated to the active catalyst 242, but is not plated to inactive catalyst 241.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method of depositing a metal on a substrate, comprising the steps of:
placing a catalyst blocker on the substrate;
removing a portion of the catalyst blocker and adjacent substrate;
placing a catalyst on a surface of the substrate and on a surface of the catalyst blocker, wherein the catalyst on the surface of the substrate is active, and the catalyst on the surface of the catalyst blocker is inactive; and
depositing the metal on the active catalyst.

2. The method of claim 1, wherein the step of removing a portion of catalyst blocker precedes the step of placing the catalyst on the surface of the substrate.

3. The method of claim 1, wherein the catalyst blocker comprises of blocking agent and a resin.

4. The method of claim 3, wherein the blocking agent is selenium or dithiocarbamate.

5. The method of claim 3, wherein the resin contains a solvent

6. The method of claim 4, wherein the selenium is amorphous selenium.

7. The method of claim 3, wherein the resin comprises at least one of the group consisting of an epoxy, a polyurethane, a polyester, a silicone, a melamine resin, a polyimide, a cyanate ester, a phenol resin, a bis-maleimide/triazine, a fluorocarbon, a liquid crystal resin, or a urea resin.

8. The method of claim 5, wherein the solvent comprises at least one of the group consisting of a carbon disulfide solvent or a solvent for a base resin.

9. The method of claim 8, wherein the solvent for the base resin comprises at least one of the group consisting of a solvent for epoxy, polyurethane, polyester, silicone, melamine resin, polyimide, cyanate ester, phenol resin, bis-maleimide/triazine, fluorocarbon, liquid crystal resin, or urea resin.

10. The method of claim 1, wherein the substrate comprises at least one of the group consisting of a polyimide, a cloth, a plastic, a metal, or a ceramic.

11. The method of claim 1, wherein the step of removing the catalyst blocker is performed by at least one of the group consisting of a laser ablation or milling.

12. The method of claim 11, wherein the laser ablation is performed by using at least one of the group consisting of a UV, a CO2, a YAG, or an excimer laser.

13. The method of claim 11, wherein the milling is performed using a numerical control (NC) mill.

14. The method of claim 1, wherein the catalyst comprises at least one of the group consisting of palladium, platinum, rhodium, iridium, cobalt, nickel, copper, gold, or silver.

15. The method of claim 1, wherein the metal comprises at least one of the group consisting of copper, nickel, cobalt, tin, silver, gold, palladium, platinum, or rhodium.

16. The method of claim 1, wherein the portion of the catalyst blocker and adjacent substrate is removed in a pattern.

17. The method of claim 16, wherein the pattern is an electrical circuit pattern.

18. A method of creating a pattern for plating a metal to a substrate, comprising the steps of:
placing a catalyst blocker on the substrate;
removing a portion of the catalyst blocker and adjacent substrate to form at least a portion of the pattern; and
placing a catalyst on a surface of the substrate and on a surface of the catalyst blocker, wherein the catalyst on the surface of the substrate is active, and the catalyst on the surface of the catalyst blocker is inactive.

19. The method of claim 18, wherein the pattern is an electrical circuit pattern.
